(19) United States
(12) Patent Application Publication
(10) Pub. No.: US 2026/0095131 A1
(43) Pub. Date: Apr. 2, 2026

(54) COUPLER FOR AMPLIFIED SIGNAL COUPLING AND CHIP INCLUDING THE SAME

(71) Applicant: SAMSUNG ELECTRONICS CO., LTD., Suwon-si (KR)

(72) Inventors: GeonHo PARK, Suwon-si (KR); Kyunghwan Kim, Suwon-si (KR); Byeongtaek Moon, Suwon-si (KR); Hyunchul Park, Suwon-si (KR); Sangmin Yoo, Suwon-si (KR); Joonhoi Hur, Suwon-si (KR)

(73) Assignee: SAMSUNG ELECTRONICS CO., LTD., Suwon-si (KR)

(21) Appl. No.: 19/347,090

(22) Filed: Oct. 1, 2025

(30) Foreign Application Priority Data
Oct. 2, 2024 (KR) 10-2024-0134176

(51) Int. Cl. H03F 1/56; H01F 38/14; H03F 3/20

(52) U.S. Cl. CPC H03F 1/565; H01F 38/14; H03F 3/20; H03F 2200/451; H03F 2200/537

(57) ABSTRACT

A coupler includes: a first unit circuit connected between a first differential line pair and a single-ended line; a second unit circuit connected between a second differential line pair and the single-ended line; a plurality of transmission lines including a first group of transmission lines connected between the first differential line pair and a crossed differential line pair, and a second group of transmission lines connected between the second differential line pair and the crossed differential line pair; and an isolation resistor. The first unit circuit includes: a first transformer connected to the first differential line pair and the single-ended line; and a second-side capacitor. The second unit circuit includes: a second transformer connected to the second differential line pair and the single-ended line; and a second-side capacitor.

### CROSS-REFERENCE TO RELATED APPLICATION

This application claims priority to Korean Patent Application No. 10-2024-0134176, filed on Oct. 2, 2024, in the Korean Intellectual Property Office, the disclosure of which is herein incorporated by reference in its entirety.

### BACKGROUND

One or more example embodiments relate to a coupler for amplified signal coupling and a chip including the same.

5G New Radio communication is driving development of radio-frequency integrated chips (RFICs) used for communication in a millimeter-wave band such as frequency range 2 (FR2). In high-frequency bands such as millimeter-wave range, transistor performance may deteriorate due to factors such as parasitic elements. In addition, as a complementary metal-oxide semiconductor (CMOS) process used in RFIC design is scaled down, a supply voltage level decreases. The degradation in the transistor performance and the decrease in the supply voltage level directly results in a reduction in output power of a power amplifier.

In addition, the load impedance of a power amplifier may vary depending on a mobile communication environment, causing fluctuations in output power and power efficiency. Accordingly, there is a need for a power amplifier that is insensitive to load impedance.

### SUMMARY

Example embodiments provide a coupler for amplified signal coupling and a chip including the same.

According to an aspect of an example embodiment, a coupler includes a first unit circuit connected between a first differential line pair and a single-ended line; a second unit circuit connected between a second differential line pair and the single-ended line; a plurality of transmission lines including a first group of transmission lines connected between the first differential line pair and a crossed differential line pair, and a second group of transmission lines connected between the second differential line pair and the crossed differential line pair; and an isolation resistor connected to the crossed differential line pair. The first unit circuit includes: a first transformer having a first side connected to the first differential line pair and a second side connected to the single-ended line; and a second-side capacitor connected in parallel to the second side of the first transformer. The second unit circuit includes: a second transformer having a first side connected to the second differential line pair and a second side connected to the single-ended line; and a second-side capacitor connected in parallel to the second side of the second transformer.

According to another aspect of an example embodiment, a coupler includes a first unit circuit connected between a first differential line pair and a single-ended line; a second unit circuit connected between a second differential line pair and the single-ended line; a first line circuit connected between the first differential line pair and a crossed differential line pair; a second line circuit connected between the second differential line pair and the crossed differential line pair; and an isolation resistor connected to the crossed differential line pair. The first and unit circuit includes: a first transformer having a first side connected to the first differential line pair, and a second side connected to the single-ended line; and a second-side capacitor connected in parallel to the second side of the first transformer. The second unit circuit includes: a second transformer having a first side connected to the second differential line pair, and a second side connected to the single-ended line; and a second-side capacitor connected in parallel to the second side of the second transformer.

According to another aspect of an example embodiment, a chip includes a first amplifier configured to output a first amplified signal through a first differential line pair; a second amplifier configured to output a second amplified signal through a second differential line pair; and a coupler connected to the first differential line pair and the second differential line pair, and configured to couple the first amplified signal and the second amplified signal and output a coupled signal through a single-ended line. The coupler includes: a first transformer having a first side connected to the first differential line pair and a second side connected to the single-ended line; a first capacitor connected in parallel to the second side of the first transformer; a second transformer having a first side connected to the second differential line pair and a second side connected to the single-ended line; a second capacitor connected in parallel to the second side of the second transformer; a first line circuit connected between the first differential line pair and a crossed differential line pair; a second line circuit connected between the second differential line pair and the crossed differential line pair; and an isolation resistor connected to the crossed differential line pair.

### BRIEF DESCRIPTION OF DRAWINGS

The above and other aspects, features, and advantages of the present disclosure will be more clearly understood from the following description, taken in conjunction with the accompanying drawings.

FIG. 1 is a diagram illustrating a chip based on a transmission line according to example embodiments.

FIGS. 2 to 6 are circuit diagrams illustrating a transformation process of a unit circuit according to example embodiments.

FIG. 7 is a circuit diagram of a unit circuit transformed according to FIGS. 2 to 6.

FIG. 8 is a circuit diagram of a unit circuit according to example embodiments.

FIG. 9 is a diagram illustrating a 180-degree rat-race coupler, according to example embodiments.

FIG. 10 is a diagram illustrating a coupler based on a transmission line, according to example embodiments.

FIG. 11 is a diagram illustrating a coupler based on a line circuit, according to example embodiments.

FIG. 12 is a diagram illustrating a coupler based on a line circuit, according to example embodiments.

FIG. 13 is a diagram illustrating a chip based on a line circuit, according to example embodiments.

FIG. 14 is a circuit diagram illustrating an example of the chip of FIG. 13, according to example embodiments.

FIGS. 15 to 17 are diagrams illustrating examples of simulation waveforms for a coupler according to example embodiments.

FIG. 18 is a diagram illustrating a transformer array included in a coupler according to example embodiments.

FIG. 19 is a diagram illustrating a coupler according to example embodiments.

FIG. 20 is a diagram illustrating a wireless communication device according to example embodiments.

### DETAILED DESCRIPTION

Hereinafter, example embodiments will be described with reference to the accompanying drawings. Embodiments described herein are example embodiments, and thus, the present disclosure is not limited thereto, and may be realized in various other forms. Each example embodiment provided in the following description is not excluded from being associated with one or more features of another example or another example embodiment also provided herein or not provided herein but consistent with the present disclosure. It will be understood that when an element or layer is referred to as being “on,” “connected to” or “coupled to” another element or layer, it can be directly on, connected or coupled to the other element or layer, or intervening elements or layers may be present. By contrast, when an element is referred to as being “directly on,” “directly connected to” or “directly coupled to” another element or layer, there are no intervening elements or layers present.

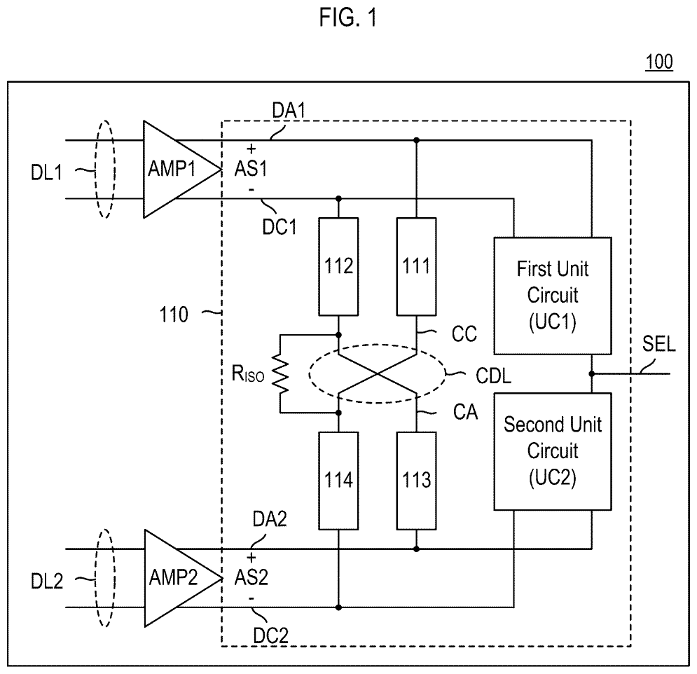

FIG. 1 is a diagram illustrating a chip based on a transmission line according to example embodiments.

Referring to FIG. 1, a chip 100 according to some example embodiments may include a first amplifier AMP1, a second amplifier AMP2, and a coupler 110.

The first amplifier AMP1 may be configured to output a first amplified signal AS1 through a first differential line pair DL1, and the second amplifier AMP2 may be configured to output a second amplified signal AS2 through a second differential line pair DL2. For example, each amplifier may be connected to each differential line pair and amplify a signal, applied to the differential line pair, to output an amplified signal. Accordingly, the amplified signal output through the differential line pair may be a differential signal.

Each amplifier may be connected to the coupler 110 through each differential line pair. For example, each amplified signal may be applied to the coupler 110 through each differential line pair.

In some example embodiments, the first amplifier AMP1 and the second amplifier AMP2 may amplify signals applied to each differential line pair and output the amplified signals, the first amplified signal AS1 and the second amplified signal AS2, in a direction of a single-ended line SEL. For example, each of the first amplifier AMP1 and the second amplifier AMP2 may be a power amplifier.

The coupler 110 may be connected between the first differential line pair DL1 and the second differential line pair DL2, and the single-ended line SEL.

In some example embodiments, the coupler 110 may be configured to couple the first amplified signal AS1 and the second amplified signal AS2, respectively amplified from the first amplifier AMP1 and the second amplifier AMP2, and output the coupled signal to the single-ended line SEL.

In some example embodiments, the coupler 110 may include a first unit circuit UC1, a second unit circuit UC2, a plurality of transmission lines 111 to 114, and an isolation resistor R_{ISO}.

The first unit circuit UC1 may have one side to which the first differential line pair DL1 connected, and the other side to which the single-ended line SEL connected. The one side of the first unit circuit UC1 may correspond to an output terminal of the first amplifier AMP1. In the present application, the differential line pair may correspond to a differential port, and the single-ended line SEL may correspond to a single-ended port. The second unit circuit UC2 has one side to which the second differential line pair DL2 is connected, and the other side to which the single-ended line SEL is connected. The one side of th second unit circuit UC2 may correspond to an output terminal of the second amplifier AMP2.

The first unit circuit UC1 may provide the first amplified signal AS1, amplified from the first amplifier AMP1, to the single-ended line SEL. The second unit circuit UC2 may provide the second amplified signal AS2, amplified from the second amplifier AMP2, to the single-ended line SEL.

In some example embodiments, the first unit circuit UC1 and the second unit circuit UC2 may be configured to operate as a differential-to-single-ended transmission line having a characteristic impedance with a first value (or magnitude) and a phase with a second value (or magnitude). In the present application, the differential-to-single-ended transmission line may be defined as a transmission line having one side connected to a differential line pair and the other side connected to a single-ended line SEL.

In some example embodiments, the first unit circuit UC1 and the second unit circuit UC2 may be configured to provide impedance matching and signal conversion between the differential line pair and the single-ended line SEL. For example, the differential-to-single-ended transmission line, defined to be equivalent to each of the first unit circuit UC1 and the second unit circuit UC2, may have a differential characteristic impedance defined in the differential line pair and a single-ended characteristic impedance defined in the single-ended line SEL. The differential characteristic impedance or the single-ended characteristic impedance may have a value allowing each of the first unit circuit UC1 and the second unit circuit UC2 to provide impedance matching between the differential line pair and the single-ended line SEL.

When impedance matching is provided through the first unit circuit UC1 and the second unit circuit UC2, the impedance defined at the output terminal of each of the first amplifier AMP1 and the second amplifier AMP2 (or load impedance of an amplifier) may correspond to a reference impedance. The reference impedance can be defined as an impedance allowing output power on the load side to have a maximum value based on the amplification of the first amplifier AMP1 and the second amplifier AMP2. For example, the output power may have a maximum value through impedance matching.

Furthermore, signals flowing through the first differential line pair DL1 and the second differential line pair DL2 (for example, the output signals of the first amplifier AMP1 and the second amplifier AMP2) and a signal flowing through the single-ended line SEL may be converted to each other through the first unit circuit UC1 and the second unit circuit UC2. For example, the first unit circuit UC1 and the second unit circuit UC2 may convert each amplified signal, a differential signal, into a single-ended signal, and vice versa.

In some example embodiments, the second value of the differential-to-single-ended transmission line equivalent to each of the first unit circuit UC1 and the second unit circuit UC2 may be 90 degrees. For example, each of the first unit circuit UC1 and the second unit circuit UC2 may be configured to be equivalent to a differential-to-single-ended transmission line having a length of λ/4 (where λ is a wavelength of a signal).

A plurality of transmission lines may be connected to one of the first differential line pair DL1 and the second differential line pair DL2 and a crossed differential line pair CDL. For example, at least a portion of the transmission lines may be connected to the first differential line pair DL1 and the crossed differential line pair CDL, and the remaining portion of the transmission lines may be connected to the second differential line pair DL2 and the crossed differential line pair CDL.

The crossed differential line pair CDL may include a crossed anode line CA and a crossed cathode line CC intersecting the crossed anode line CA in at least some regions. Hereinafter, in the present application, it is natural that an “anode line” may be configured as a “cathode line,” and the “cathode line” may also be configured as the “anode line.” Also, the anode line may be referred to as a differential signal line, a high signal line, or the like, and the cathode line may be referred to as an inverted differential signal line, a low signal line, or the like.

In some example embodiments, the plurality of transmission lines may have the same characteristic impedance and propagation characteristics to cause the same phase difference. For example, the characteristic impedance may be 1/\sqrt{2} times the differential characteristic impedance (or reference impedance) defined for a single differential line pair. For example, the phase difference may be 90 degrees.

In some example embodiments, the plurality of transmission lines may include a first transmission line to a fourth transmission line 111 to 114.

The first transmission line 111 may be connected to the first anode line DA1 of the first differential line pair DL1 and the crossed cathode line CC. The second transmission line 112 may be connected to the first cathode line DC1 of the first differential line pair DL1 and the crossed anode line CA. For example, each of the first transmission line 111 and the second transmission line 112 may have one side connected to a single anode line, and the other side connected to a single cathode line. The first transmission line 111 and the second transmission line 112 are connected to lines having opposite polarities, so that the first transmission line 111 and the second transmission line 112 may cause an additional phase difference of 180 degrees in addition to a basic phase difference.

For example, when the first transmission line 111 and the second transmission line 112 have impedance and propagation characteristics, including line lengths, causing a phase difference of 90 degrees, they may be connected to lines having opposite polarities to have an additional phase difference of 180 degrees. Thus, signals flowing through the first transmission line 111 and the second transmission line 112 may have a total phase difference of 270 degrees.

A third transmission line 113 may be connected to a second anode line DA2 of the second differential line pair DL2 and the crossed anode line CA. A fourth transmission line 114 may be connected to a second cathode line DC2 of the second differential line pair DL2 and the crossed cathode line CC. For example, unlike the first transmission line 111 and the second transmission line 112, each of the third transmission line 113 and the fourth transmission line 114 may have both one side and the other side connected to lines having the same polarity.

Accordingly, the third transmission line 113 and the fourth transmission line 114 may maintain the basic phase difference.

The isolation resistor R_{ISO} may be connected to the crossed differential line pair CDL. For example, the isolation resistor R_{ISO} may have one side connected to the crossed anode line CA, and the other side connected to the crossed cathode line CC. The isolation resistor R_{ISO} may provide isolation between the differential line pairs (and the signals flowing through the differential line pairs).

As described above, when the first unit circuit UC1 and the second unit circuit UC2 are equivalently configured as differential-to-single-ended transmission lines, the first unit circuit UC1 and the second unit circuit UC2 may be regarded as transmission lines connected to the first differential line pair DL1 and the second differential line pair DL2 corresponding to input ports and the single-ended line SEL corresponding to an output port. Also, the isolation resistor R_{ISO} may be connected to the crossed differential line pair CDL corresponding to an isolation port.

In addition, at least a portion of the plurality of transmission lines (for example, the first transmission line 111 and the second transmission line 112) may be connected to the first differential line pair DL1 corresponding to the input port and the crossed differential line pair CDL corresponding to the isolation port. In addition, the remaining portion of the plurality of transmission lines (for example, the third transmission line 113 and the fourth transmission line 114) may be connected to the second differential line pair DL2 corresponding to the input port and the crossed differential line pair CDL corresponding to the isolation port.

Accordingly, the coupler 110 may have characteristics of a 180-degree rat-race coupler. For example, the first amplified signal AS1 and the second amplified signal AS2 coupled through the coupler 110 do not need to have a phase difference of 90 degrees, unlike the 90-degree rat-race coupler 110. In addition, the coupler 110 may invert the phase of one of the amplified signals AS1 and AS2 and couple the amplified signals.

As described above, the coupler 110 may invert a phase of one of the amplified signals AS1 and AS2 and couple the amplified signals. Accordingly, the first amplifier AMP1, the second amplifier AMP2, and the coupler 110 may be regarded as a balanced amplifier with respect to the chip 100. The chip 100 may exhibit characteristics of being insensitive to load impedance while improving output power through a balanced amplification operation.

As described above, the chip 100 may supply high output power by coupling amplified signals without the need to generate a phase difference of 90 degrees between the amplified signals to be combined, provide isolation between the amplified signals, and provide impedance matching and signal conversion between differential and single-ended transmission lines.

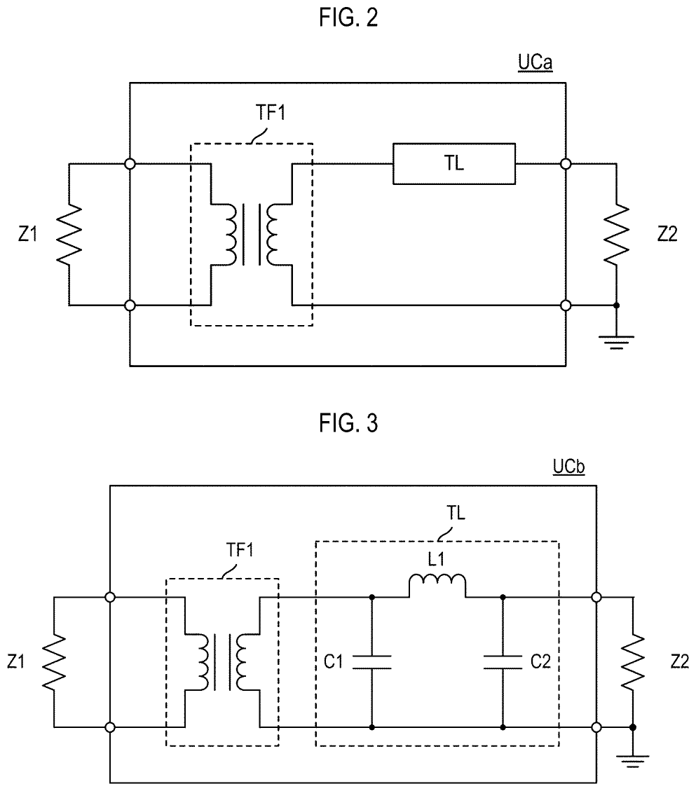

FIGS. 2 to 6 are circuit diagrams illustrating a conversion process of a unit circuit, according to example embodiments, and FIG. 7 is a circuit diagram of the unit circuit converted according to FIGS. 2 to 6. Hereinafter, in the present application, the “unit circuit” may refer to at least one of the first unit circuit UC1 or the second unit circuit UC2.

Referring to FIG. 2, a unit circuit UCa may include a first transformer TF1 and a transmission line TL. Impedances connected to each side of the first transformer TF1 are impedance conversion (or matching) targets, and impedance at opposite ends of a first side of the first transformer TF1 is defined as first impedance Z1, and the transmission line TL is connected to a second side of the first transformer TF1. Also, impedance at opposite ends of a second side of the first transformer TF1 is defined as second impedance Z2, and the transmission line TL is connected in series to the second impedance Z2. Also, one end of the second side of the first transformer TF1 is grounded. Accordingly, a signal on the first side of the first transformer TF1 may be a differential signal, and a signal on the second side may be a single-ended signal.

The first transformer TF1 may be configured as a type of matching network to provide conversion between the first impedance Z1 and the second impedance Z2. A turn ratio of the first transformer TF1 may be set based on a relationship between the first impedance Z1 and the second impedance Z2. In some example embodiments, when the first impedance Z1 is 2*Z2, the turn ratio of the first transformer TF1 may be set to \sqrt{2}:1. Alternatively, when the first impedance Z1 is k*Z2 (where k is a non-zero positive real number), the turn ratio of the first transformer TF1 may be set to \sqrt{k}:1.

For example, when the turn ratio of the first transformer TF1 is 2:1, the unit circuit may match impedance viewed from the first side of the first transformer TF1 (for example, the first impedance Z1) to twice the second impedance Z2.

The transmission line TL may have impedance and propagation characteristics that cause the same phase difference. In some example embodiments, the transmission line TL may be configured to have a specific characteristic impedance and to cause a phase difference of 90 degrees. For example, the transmission line TL may have a length of λ/4. The characteristic impedance of the transmission line may have various values depending on the number of amplifiers coupled to the unit circuit.

Through the unit circuit UCa, a differential signal may be converted to a single-ended signal and vice versa, and the first impedance Z1 may be converted to the second impedance Z2 and vice versa.

In a unit circuit UCb of FIG. 3, the transmission line TL of FIG. 2 may be equivalently converted to a C-L-C circuit (for example, a low-pass filter). The C-L-C circuit may include a first inductor L1, a first capacitor C1, and a second capacitor C2, configured in a π(pi) shape across opposite ends of the second side of the first transformer TF1. Inductance L_{Q} of the first inductor L1 may be set to Z_{C}/ω, and capacitance C_{Q} of the first capacitor C1 and the second capacitor C2 may be set to 1/(ωZ_{C}), where ω is an angular frequency of a signal.

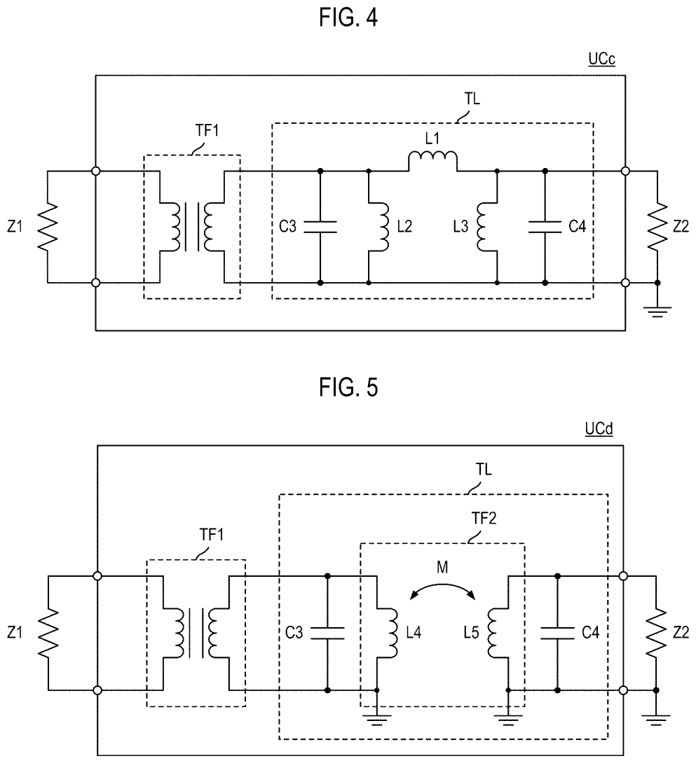

In a unit circuit UCc of FIG. 4, a first capacitor C1 included in a C-L-C circuit of FIG. 3 may be equivalently implemented as a third capacitor C3 and a second inductor L2 connected in parallel, and a second capacitor C2 may be equivalently implemented as a fourth capacitor C4 and a third inductor L3 connected in parallel. When capacitance of the third capacitor C3 and the fourth capacitor C4 is C_{P} and inductance of the second inductor L2 and the third inductor L3 is L_{P}, C_{Q}=C_{P}−1/(ω²L_{P}).

In a unit circuit UCd of FIG. 5, the first inductor L1, the second inductor L2, and the third inductor L3 configured in the π(pi) shape in FIG. 4 may be equivalently implemented as a second transformer TF2 having a turn ratio of 1:1. The second transformer TF2 may include a fourth inductor L4 configured on a first side and a fifth inductor L5 configured on a second side. Inductance of the fourth inductor L4 and the fifth inductor L5 is L_{X}. The inductance L_{X} may have a relationship with the inductance L_{Q}, as given by

$${L}_{Q} = {L}_{X}^{2} / M - M ,$$

where M is mutual inductance of the second transformer TF2. The inductance L_{X} may have a relationship with the inductance L_{P}, as given by L_{P}=L_{X}+M.

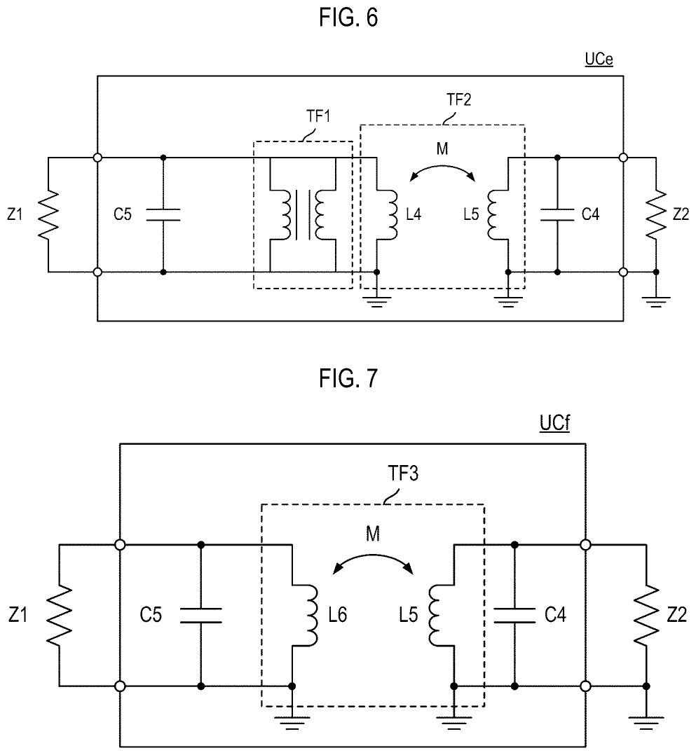

In a unit circuit UCe of FIG. 6, a third capacitor C3 connected in parallel to the fourth inductor L4 of FIG. 5 may be configured as a fifth capacitor C5 when passing to a first side of the first transformer TF1. The fifth capacitor C5 may have the capacitance that is 1/k times the capacitance C_{P} of the fourth capacitor C4. For example, when k=2, the capacitance of the fifth capacitor C5 is C_{P}/2.

In a unit circuit UCf of FIG. 7, the first transformer TF1 and the second transformer TF2 of FIG. 6 may be equivalently implemented as a third transformer TF3. The third transformer TF3 may include a sixth inductor L6 configured on a first side and a fifth inductor L5 configured on a second side. The inductance of the sixth inductor L6 may have k times the inductance L_{X} of the fifth inductor L5. For example, when k=2, the inductance of the sixth inductor L6 is 2L_{X}.

As described above, the unit circuits of FIGS. 2 to 7 are equivalent to each other. For example, through the unit circuit (UCf) of FIG. 7, a transformer for impedance matching of FIG. 2 and a transmission line TL having impedance and propagation characteristics that cause a specific phase difference may be implemented. The unit circuit UCf of FIG. 7 may be equivalently implemented with a transformer and a transmission line TL as a single transformer and capacitors connected to each transformer. Accordingly, the unit circuit UCf of FIG. 7 may provide impedance matching between the impedance at one end of the transmission line TL and the impedance at the other end of the transmission line TL, similarly to the first transformer TF1 of FIG. 2, while reducing an area and power loss caused by a multi-stage structure (the transformer and the transmission line TL). Also, the unit circuit UCf of FIG. 7 may operate as a differential-to-single-ended transmission line TL, capable of converting the differential signal of one end of the transmission line TL and the single-ended signal of the other end of the transmission line TL while reducing an area and power loss.

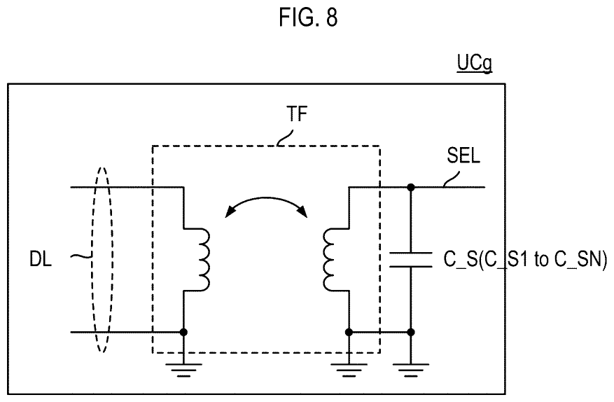

FIG. 8 is a circuit diagram of a unit circuit according to example embodiments.

Referring to FIG. 8, a unit circuit UCg according to example embodiments may be configured by omitting the fifth capacitor in the unit circuit of FIG. 7. For example, the unit circuit UCg may include a transformer TF and second-side capacitors C_S1 to C_SN.

The transformer TF may have a first side connected to a single differential line pair DL, and a second side connected to a single-ended line SEL. The transformer TF may have a turn ratio of k:1. For example, the turn ratio may be 2:1.

The second-side capacitors C_S1 to C_SN may be connected in parallel to the second side of the transformer TF. When a capacitor is additionally connected to the first side of the transformer TF (for example, the differential line pair DL), the unit circuit may operate as a differential-to-single-ended transmission line that may provide impedance matching.

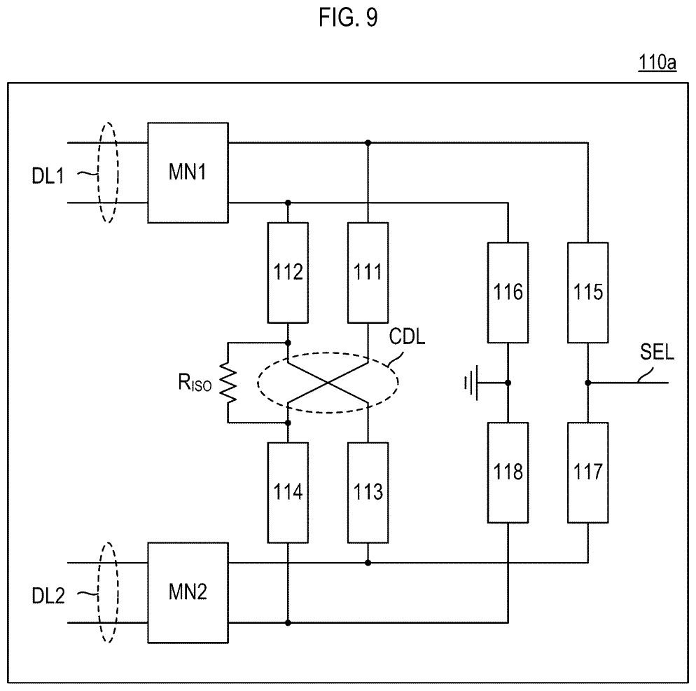

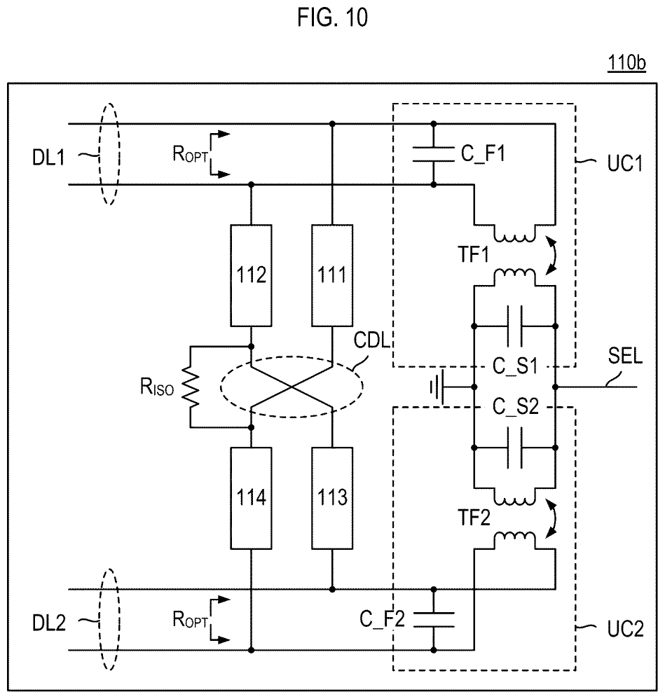

FIG. 9 is a diagram illustrating a 180-degree rat-race coupler, according to example embodiments, and FIG. 10 is a diagram illustrating a coupler based on a transmission line, according to example embodiments. Hereinafter, redundant descriptions will be omitted to avoid repetition.

Referring to FIG. 9, a 180-degree rat-race coupler 110a according to example embodiments may include first to eighth transmission lines 111 to 118, a first matching network MN1, and a second matching network MN2.

The first to fourth transmission lines 111 to 114 may be connected to either a first differential line pair DL1 or a second differential line pair DL2, and a crossed differential line pair CDL.

A fifth transmission line 115 may be connected to the first differential line pair DL1 and the single-ended line SEL, and a sixth transmission line 116 may be connected to the first differential line pair DL1 and ground. A seventh transmission line 117 may be connected to the second differential line pair DL2 and the single-ended line SEL, and an eighth transmission line 118 may be connected to the second differential line pair DL2 and ground.

For example, all of the above-described first to eighth transmission lines 111 to 118 may be configured to have the same specific characteristic impedance and may each cause a phase difference of 90 degrees. However, the first transmission line 111 and the second transmission line 112 may have a phase difference of 270 degrees because they are connected to lines having opposite polarities.

The first matching network MN1 may be connected to the first differential line pair DL1, the fifth transmission line 115, and the sixth transmission line 116 to provide matching to the differential characteristic impedance defined for the first differential line pair DL1. The second matching network MN2 may be connected to the second differential line pair DL2, the seventh transmission line 117, and the eighth transmission line 118 to provide matching to the differential characteristic impedance defined for the second differential line pair DL2.

The first matching network MN1, the second matching network MN2, and the fifth to eighth transmission lines 115 to 118 of FIG. 9 may be converted into an equivalent unit circuit, based on the unit circuits consistent with example embodiments, for example, those described above with reference to FIGS. 7 and 8.

Referring to FIG. 10, a coupler 110b according to example embodiments may include a first unit circuit UC1 and a second unit circuit UC2 configured to be equivalent with a matching network and a transmission line, a plurality of transmission lines 111 to 114, and an isolation resistor R_{ISO}.

Each of the first unit circuit UC1 and the second unit circuit UC2 may be configured as described above, for example, with reference to FIGS. 2 to 8. In some example embodiments, each of the first unit circuit UC1 and the second unit circuit UC2 may include a transformer, having a first side connected to a single differential line pair and a second side connected to a single-ended line SEL, and a second-side capacitor connected in parallel to the second side of the transformer.

In some example embodiments, each of the first unit circuit UC1 and the second unit circuit UC2 may further include a first-side capacitor connected in parallel to the first side. For example, the first-side capacitor may have a capacitance that is 1/k times the capacitance of the second-side capacitor. Hereinafter, the first-side capacitor may be omitted.

For example, the first unit circuit UC1 may include a first transformer TF1, a first-side capacitor C_F1, and a second-side capacitor C_S1. A first side of the first transformer TF1 may be connected to the first differential line pair DL1, and a second side of the first transformer TF1 may be connected to the single-ended line SEL. The first-side capacitor C_F1 may be connected in parallel to the first side of the first transformer TF1. The second-side capacitor C_S1 may be connected in parallel to the second side of the first transformer TF1.

The second unit circuit UC2 may include a second transformer TF2, a first-side capacitor C_F2, and a second-side capacitor C_S2. A first side of the second transformer TF2 may be connected to the second differential line pair DL2, and the second side of the second transformer TF2 may be connected to the single-ended line SEL. The first-side capacitor C_F2 may be connected in parallel to the first side of the second transformer TF2. The second-side capacitor C_S2 may be connected in parallel to the second side of the second transformer TF2.

In some example embodiments, each of the first transformer TF1 and the second transformer TF2 may be configured to have a turn ratio of 2:1.

As discussed above, the first unit circuit UC1 and the second unit circuit UC2 may be configured to be equivalent to the unit circuit of FIG. 2, providing impedance matching and signal conversion between differential and single-ended signals with low power loss and a small area.

Each unit circuit is equivalently configured to include the first transformer of FIG. 2, providing matching to the differential characteristic impedance defined in a single differential line pair. For example, when k=2 and the single-ended characteristic impedance defined in the single-ended line SEL is R_{OPT}/2, the differential characteristic impedance may be matched to R_{OPT}. R_{OPT} may correspond to the above-described reference impedance.

In some example embodiments, each transformer may be configured to allow a bias current to flow through a center tap thereof. When a supply voltage is connected to the center tap of each transformer, the bias current may be generated through the supply voltage. The bias current may be provided to a transistor included in an amplifier that may be connected to the coupler 110b.

Together with the first unit circuit UC1 and the second unit circuit UC2 configured to be equivalent to a matching network and a transmission line, the plurality of transmission lines 111 to 114 may enable the coupler 110b to have characteristics of a 180-degree rat-race coupler. Also, the isolation resistor R_{ISO} connected to the crossed differential line pair CDL may provide isolation for the first differential line pair DL1 and the second differential line pair DL2.

In some example embodiments, the isolation resistor R_{ISO} may be configured to have an impedance equal in magnitude (for example, R_{OPT}) to the differential characteristic impedance defined in the single differential line pair.

The coupler 110b may have the characteristics of the 180-degree rat-race coupler while providing impedance matching with low power loss and small area. Accordingly, the coupler 110b does not need to generate a phase difference of 90 degrees between signals to be amplified. Also, the coupler 110b may provide high isolation between differential line pairs. In addition, the coupler 110b may provide signal conversion between the differential line pair and the single-ended line SEL.

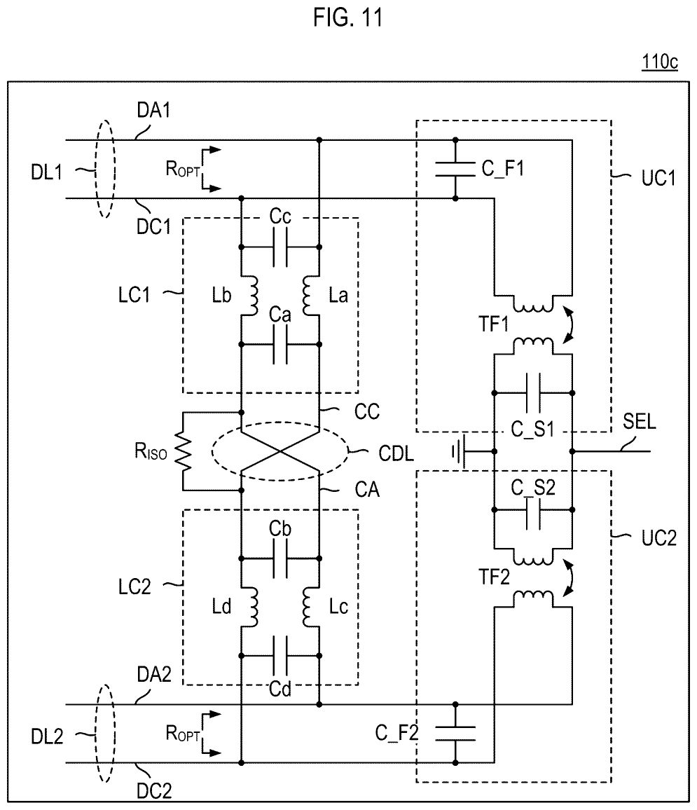

FIG. 11 is a diagram illustrating a coupler based on a transmission line circuit according to example embodiments.

Referring to FIG. 11, a coupler 110c according to example embodiments may include a first unit circuit UC1, a second unit circuit UC2, an isolation resistor R_{ISO}, a first line circuit LC1, and a second line circuit LC2. The first unit circuit UC1 and the second unit circuit UC2 may be configured to be identical to the unit circuits of FIG. 10. In some example embodiments, the isolation resistor R_{ISO} may be configured to have an impedance equal in magnitude to a differential characteristic impedance defined in a single differential line pair.

The first line circuit LC1 may be connected to a first differential line pair DL1 and a crossed differential line pair CDL, and the second line circuit LC2 may be connected to a second differential line pair DL2 and a crossed differential line pair CDL. The first line circuit LC1 and the second line circuit LC2 may be configured to be equivalently the same as the plurality of transmission lines of FIG. 10. For example, characteristic impedance of each of the transmission line, which are equivalently the same, may be 1/\sqrt{2} times the differential characteristic impedance (or reference impedance) defined in a single differential line pair, and a phase difference may be 90 degrees.

In some example embodiments, the first line circuit LC1 may include a first inductor La, a second inductor Lb, and a first capacitor Ca.

The first inductor La may be connected to a first anode line DA1 of the first differential line pair DL1 and a crossed cathode line CC of the crossed differential line pair CDL. The second inductor Lb may be connected to a first cathode line DC1 of the first differential line pair DL1 and a crossed anode line CA of the crossed differential line pair CDL. The first capacitor Ca may be connected in parallel to an isolation resistor R_{ISO}. For example, the first capacitor Ca may be connected to the crossed differential line pair CDL.

In some example embodiments, the second line circuit LC2 may include a third inductor Lc, a fourth inductor Ld, and a second capacitor Cb.

The third inductor Lc may be connected to a second anode line DA2 of the second differential line pair DL2 and a crossed anode line CA. The fourth inductor Ld may be connected to a second cathode line DC2 of the second differential line pair DL2 and the crossed cathode line CC. The second capacitor Cb may be connected in parallel to the isolation resistor R_{ISO}. For example, the second capacitor Cb may be connected to the crossed differential line pair CDL.

In some example embodiments, the first line circuit LC1 may further include a third capacitor Cc connected to the first differential line pair DL1. In some example embodiments, the second line circuit LC2 may further include a fourth capacitor Cd connected to the second differential line pair DL2.

The first line circuit LC1 may be configured to be equivalent to a transmission line connected to the first anode line DA1 and a transmission line connected to the first cathode line DC1. For example, the first line circuit LC1 may be a line circuit in which a transmission line of each line is converted into a C-L-C circuit (for example, see FIG. 3). Similarly, the second line circuit LC2 may be configured to be equivalent to a transmission line connected to the second anode line DA2 and a transmission line connected to the second cathode line DC2.

The first to fourth inductors La to Ld and the first to fourth capacitors Ca to Cd may have inductances or capacitances defined by a characteristic impedance and an angular frequency of a transmission line, as described in FIG. 3.

As discussed above, the coupler 110c may reduce a chip size by implementing transmission lines that cause a phase difference of 90 degrees using passive components. In addition, the coupler 110c may have characteristics of a 180-degree rat-race coupler while providing impedance matching and signal conversion between differential and single-ended signals with low power loss and a small area.

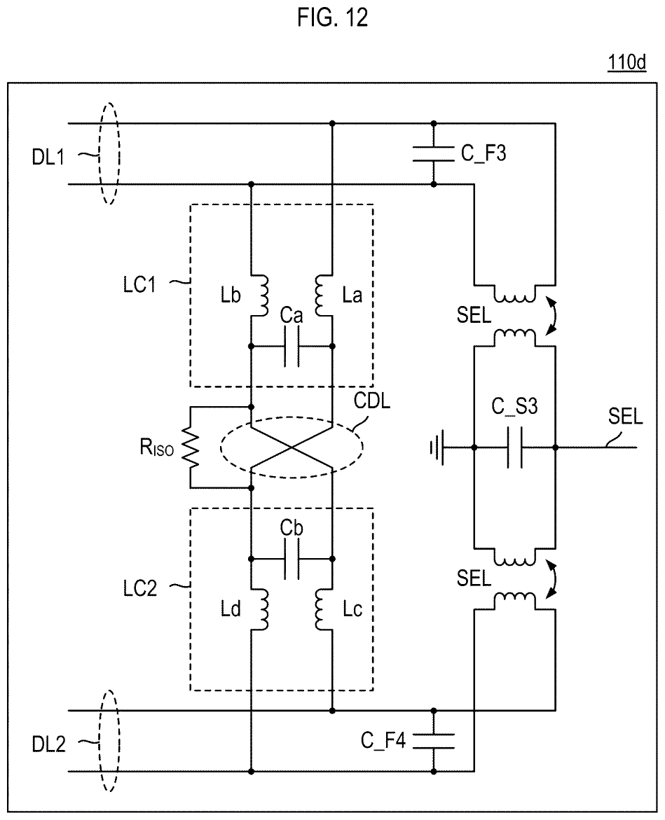

FIG. 12 is a diagram illustrating a coupler based on a transmission line circuit, according to example embodiments.

Referring to FIG. 12, a coupler 110d according to example embodiments may include certain components that are either omitted from or coupled to the coupler of FIG. 11.

In some example embodiments, a third capacitor included in the first line circuit of FIG. 11 may be coupled to a first-side capacitor of a first unit circuit. The coupled capacitor is an equivalent first-side capacitor C_F3. Similarly, a fourth capacitor included in the second line circuit of FIG. 11 may be coupled to a first-side capacitor of a second unit circuit. The coupled capacitor may be an equivalent first-side capacitor C_F4.

For example, the first-side capacitor C_F3 may have a capacitance corresponding to the sum of the capacitance of the third capacitor of FIG. 11 and the capacitance of the first-side capacitor. For example, the first-side capacitor C_F4 may have a capacitance corresponding to the sum of the capacitance of the fourth capacitor of FIG. 11 and the capacitance of the first-side capacitor.

In some example embodiments, the second-side capacitors included in the first unit circuit and the second unit circuit of FIG. 11 may be coupled to a single second-side capacitor C_S3.

For example, the second-side capacitor C_S3 may have a capacitance corresponding to the sum of the capacitance of the second-side capacitor of FIG. 11 and the capacitance of the second-side capacitor.

The coupler 110d may decrease the number of passive components.

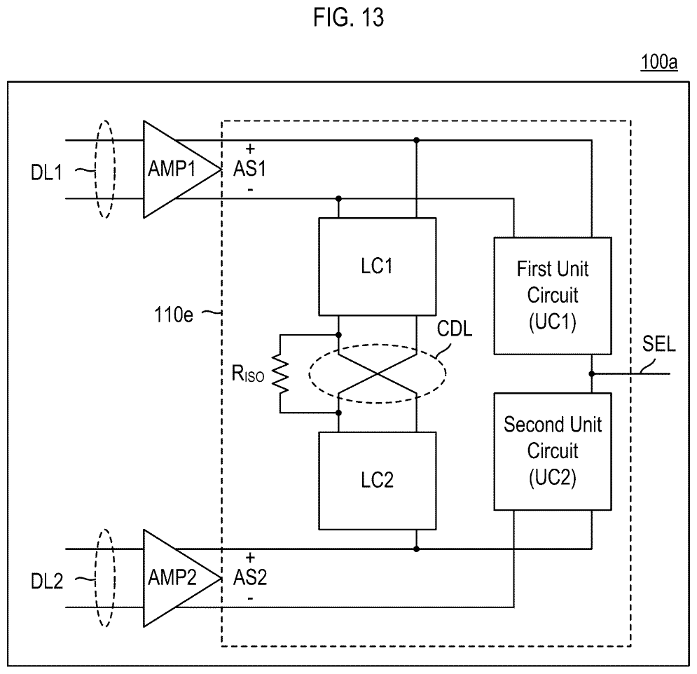

FIG. 13 is a diagram illustrating a chip based on a transmission line circuit according to example embodiments.

Referring to FIG. 13, a chip 100a according to example embodiments may include a first amplifier AMP1, a second amplifier AMP2, and a coupler 110e. The coupler 110e may couple a first amplified signal AS1 and a second amplified signal AS2, respectively amplified by the first amplifier AMP1 and the second amplifier AMP2, and provide the coupled signal to a single-ended line.

In some example embodiments, a first unit circuit UC1 and a second unit circuit UC2 included in the coupler 110e may be configured as described above with reference to FIGS. 2 to 8.

In some example embodiments, a first line circuit LC1 and a second line circuit LC2 included in the coupler 110e may be configured as described above, for example with reference to the line circuits of FIGS. 11 and 12.

The coupler 110e may invert a phase of one of the first and second amplified signals AS1 and AS2, and couple amplified signals. Therefore, the first amplifier AMP1, the second amplifier AMP2, and the coupler 110e may be regarded as a balanced amplifier, with respect to the chip 100a. The chip 100a may have a characteristic of being insensitive to load impedance while improving output power through balanced amplification operation.

The chip 100a may supply high output power by coupling amplified signals without the need to generate a phase difference of 90 degrees between the amplified signals to be combined, provide isolation between the amplified signals, and provide impedance matching and signal conversion between differential and single-ended transmission lines. In addition, the chip 100a may reduce power loss and area by replacing transmission lines with equivalently configured circuits.

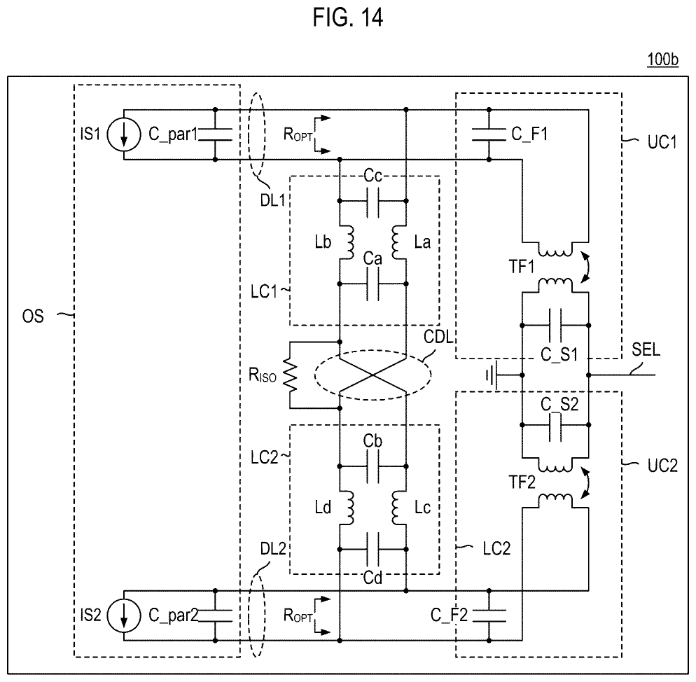

FIG. 14 is a circuit diagram illustrating an example of the chip of FIG. 13, according to example embodiments.

Referring to FIG. 14, a chip 100b according to example embodiments may include a first unit circuit UC1, a second unit circuit UC2, a first line circuit LC1, a second line circuit LC2, an isolation resistor R_{ISO}, and an output terminal circuit OS.

The output terminal circuit OS may correspond to an output terminal of an amplifier and include a first current source IS1 and a second current source IS2 connected to each differential line pair. The first current source IS1 and the second current source IS2 are voltage-controlled current sources and may correspond to a transistor included in an output terminal of one of the first amplifier AMP1 and the second amplifier AMP2. A capacitor connected in parallel with each current source may be a parasitic capacitance component. First parasitic capacitance component C_par1 and second parasitic capacitance component C_par2 may serve as the first-side capacitor in each unit circuit, or may replace the first-side capacitor.

According to example embodiments, when the sum of the capacitance of the first parasitic capacitance (C_par1) component and the capacitance of the third capacitor Cc is 1/k times the capacitance of the second-side capacitor C_S1, the first-side capacitor C_F1 may be omitted. Similarly, when the sum of the capacitance of the second parasitic capacitance (C_par2) component and the capacitance of the fourth capacitor Cd is 1/k times the capacitance of the second-side capacitor C_S2, the first-side capacitor C_F2 may be omitted.

Alternatively, when the first-side capacitor C_F1 is configured according to example embodiments, the second-side capacitor C_S1 may be configured to have a capacitance that is k times the sum of the capacitances of the first-side capacitor C_F1, the first parasitic capacitance C_par1, and the third capacitor Cc. Similarly, when the first-side capacitor C_F2 is configured according to example embodiments, the second-side capacitor C_S2 may be configured to have a capacitance that is k times the sum of the capacitances of the first-side capacitor C_F2, the second parasitic capacitance C_par2, and the fourth capacitor Cd.

In the chip 100b, the second-side capacitor (or in addition to the first-side capacitor) and the parasitic capacitance may operate equivalently to a differential-to-single-ended line SEL having a differential characteristic impedance of ROPT and a single-ended characteristic impedance of ROPT/2.

The chip 100b may couple amplified signals having characteristics of a 180-degree rat-race coupler with low power loss and a small area. In addition, the chip 100b does not require an additional inductor for resonance of the parasitic capacitance using the parasitic capacitance and the transformer as transmission lines of the 180-degree rat-race coupler.

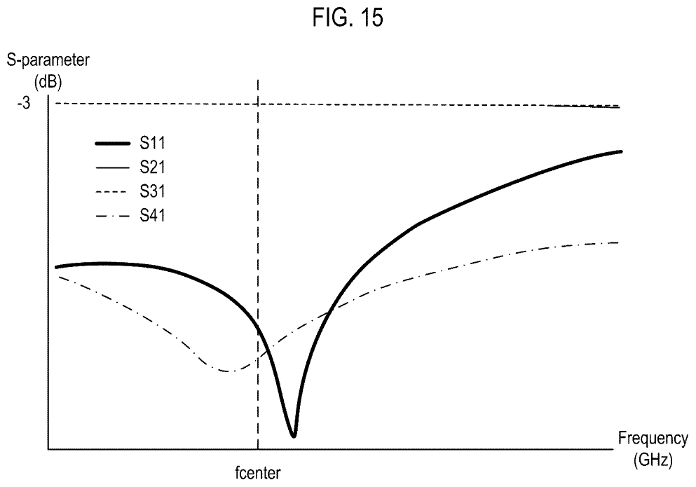

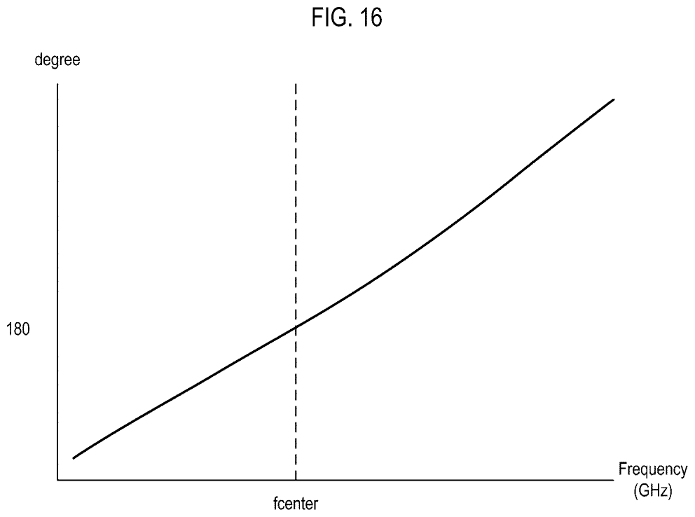

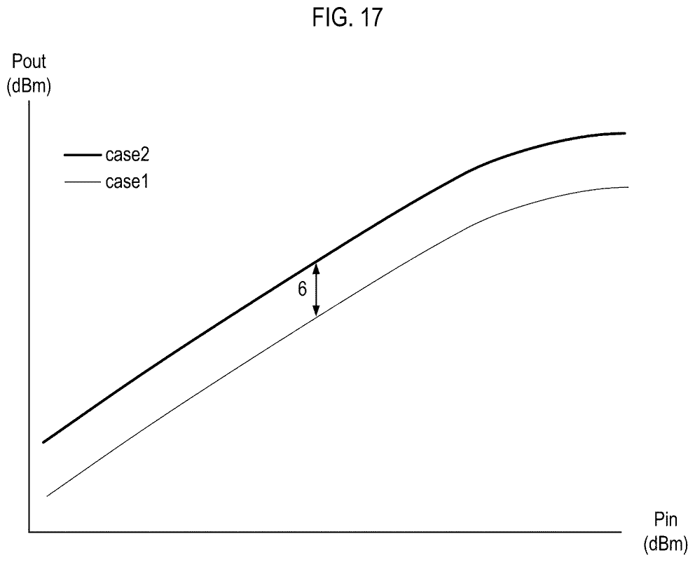

FIGS. 15 to 17 are diagrams illustrating examples of simulation waveforms for a coupler according to example embodiments. Hereinafter, a first port and a fourth port of an S-parameter, as input ports, may correspond to the first differential line pair and the second differential line pair described above, respectively. A second port may output a difference between signals of the first port and the fourth port, and the third port may output the sum of the signals of the first port and the fourth port. FIGS. 15 and 16 provide an example in which a signal is applied only to the first port. FIG. 17 illustrates an example in which signals are applied to both the first port and the fourth port.

FIG. 15 illustrates a magnitude of the S-parameters for each frequency. S-parameters S21 which is S-parameters from the first port to the second port and S31 which is S-parameters from the first port to the third port, both exhibit −3 dB at a center frequency fcenter. For example, a signal corresponding to each half of the input signal is output to the second port and the third port.

FIG. 16 illustrates a phase difference between the second port and the third port for each frequency. Output signals of the second port and the third port may exhibit a phase difference of 180 degrees at the center frequency fcenter. Accordingly, the coupler may be confirmed to operate as a 180-degree rat-race coupler.

FIG. 17 illustrates the magnitude of output power relative to input power for the second port. Case 1 represents output power when a rat-race coupler is not applied, and Case 2 represents output power when a rat-race coupler is applied, according to example embodiments. As illustrated in FIG. 17, the output power in Case 2 is 6 dBm greater than the output power in Case 1. This is because input signals are coupled through the coupler and output through a single-ended line. For example, the output power in Case 2 is about 4 times the output power in Case 1.

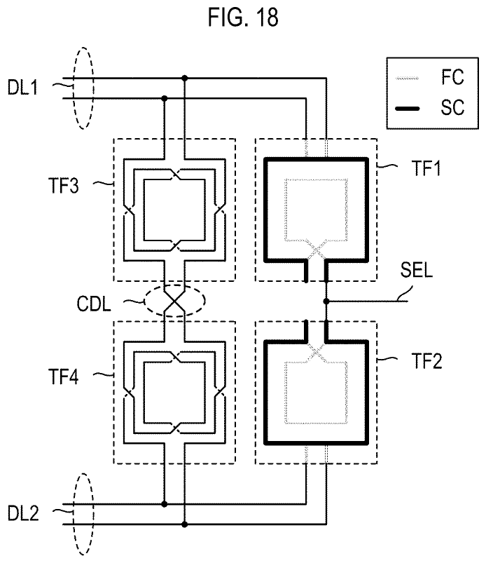

FIG. 18 is a diagram illustrating a transformer array included in a coupler according to example embodiments.

Referring to FIG. 18, the transformer array according to example embodiments may include a first transformer TF1 connected between a first differential line pair DL1 and a single-ended line SEL, a second transformer TF2 connected between a second differential line pair DL2 and a single-ended line SEL, a third transformer TF3 connected between the first differential line pair DL1 and a crossed differential line pair CDL, and a fourth transformer TF4 connected between a second differential line pair DL2 and the crossed differential line pair CDL.

For example, the first transformer TF1 and the second transformer TF2 may be transformers included in the first unit circuit UC1 and the second unit circuit UC2 described above, and the third transformer TF3 and the fourth transformer TF4 may be inductors included in the first line circuit and the second line circuit described above. Each transformer may include a first-side coil FC and a second-side coil SC.

### First Transformer TF1 and Second Transformer TF2

In the first transformer TF1 and the second transformer TF2, the first-side coils FC may be connected, respectively, to the differential line pairs. For example, the first-side coil FC may be configured to have a turn ratio of k. In FIG. 18, the turn ratio of the first-side coil FC is 2. The first-side coil FC may form k loops according to the turn ratio. As illustrated in the drawing, when the turn ratio of the first-side coil FC is 2, the first-side coil FC may include an outer loop, which overlaps a second-side coil SC, and an inner loop which does not overlap the outer loop. The outer loop and the second-side coil SC may be formed on different layers.

Opposite ends of the outer loop of the first-side coil FC may be connected to a corresponding line pair.

Each second-side coil may be commonly connected to a single-ended line. The second-side coil may be configured to have a turn ratio of 1. The second-side coil may include a single loop that overlaps the first-side coil FC but is formed on a separate layer.

The single loop may have one end connected to the single-ended line, and the other end grounded.

### Third Transformer TF3 and Fourth Transformer TF4

The third and fourth transformers may be configured to have a turn ratio of 1:1. A turn ratio of the coils included in each transformer may be set variously. Each transformer may include one or more loops depending on the turn ratio. Coils included in the third transformer may be connected to the first differential line pair DL1 and the crossed differential line pair CDL, and coils included in the fourth transformer may be connected to the second differential line pair DL2 and the crossed differential line pair CDL.

The above-described transformer array may be included in the coupler. For example, the coupler may replace a transformer and transmission lines for impedance matching with passive transformers, so that power loss and an area may be reduced.

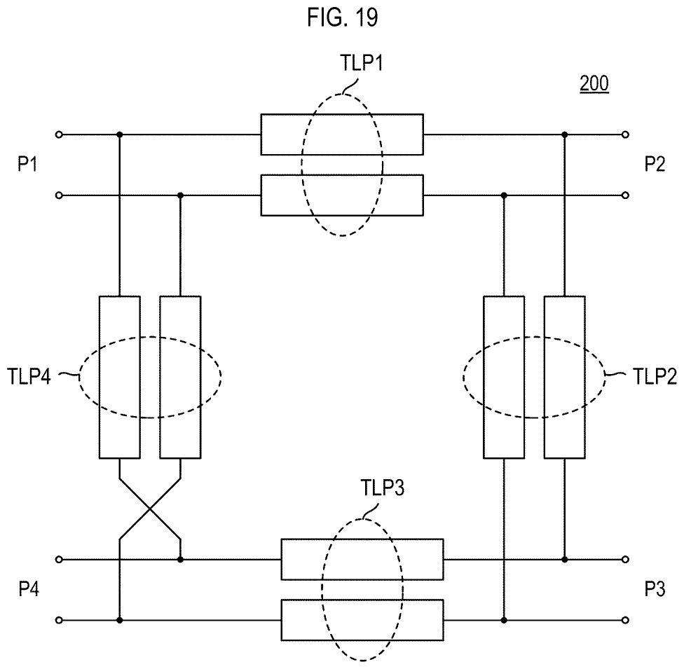

FIG. 19 is a diagram illustrating a coupler according to example embodiments.

Referring to FIG. 19, a coupler 200 according to example embodiments may be connected to first to fourth ports P1 to P4. The first port P1 and the third port P3 may be input ports to which input signals are applied, the second port P2 may be an output port, and the fourth port P4 may be an isolation port to which an isolation resistor R_{ISO} is connected. Each port is a differential port, and a transmission line may be configured for each line connected to each port.

According to various example embodiments, among first to fourth line pairs TLP1 to TLP4, at least one line pair may include a circuit equivalent to the transmission line according to example embodiments describe above, for example, with reference to FIGS. 3 to 5. One of the two ports associated with the line pair may include a single-ended line.

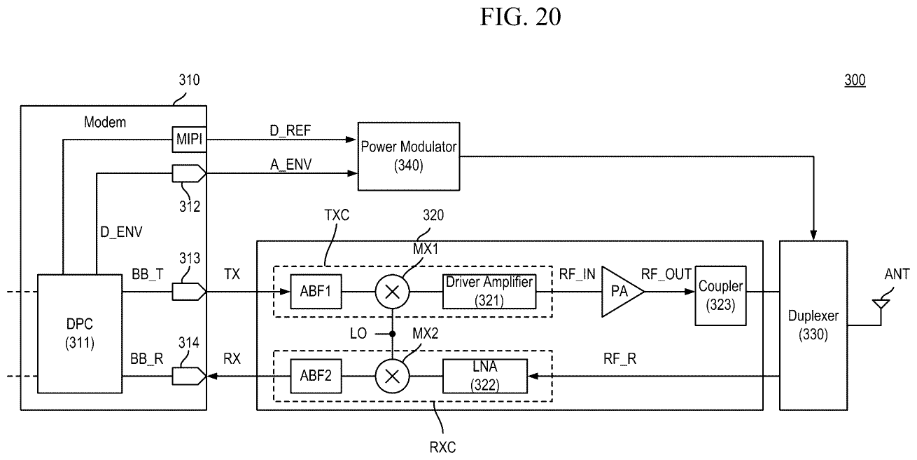

FIG. 20 is a diagram illustrating a wireless communication device according to example embodiments.

Referring to FIG. 20, the wireless communication device 300 may include a modem 310, a radio-frequency integrated circuit (RFIC) 320, a duplexer 330, a power modulator 340, and an antenna ANT.

The modem 310 may include a digital processing circuit 311, a first digital-to-analog converter (DAC) 312, a second DAC 313, an analog-to-digital converter (ADC) 314, and a mobile industry processor interface (MIPI). The modem 310 may process a baseband signal BB_T (for example, including an I signal and a Q signals) including information to be transmitted through the digital processing circuit 311 based on various communication schemes. The modem 310 may process a received baseband signal BB_R through the digital processing circuit 311 based on various communication schemes.

For example, the modem 310 may process a signal to be transmitted or a received signal based on a communication scheme such as orthogonal frequency division multiplexing (OFDM), orthogonal frequency division multiple access (OFDMA), wideband code multiple access (WCDMA), and high speed packet access+ (HSPA+). In addition, the modem 310 may process signals based on various types of communication schemes (for example, various communication schemes to which a technology for modulating or demodulating an amplitude and a frequency of the baseband signal BB_T or BB_R is applied).

The modem 310 may extract an envelope of the baseband signal BB_T through the digital transmission processing circuit 311 and may generate a digital envelope signal D_ENV based on the extracted envelope.

According to some example embodiments, the modem 310 may generate an average power signal D_REF based on an average power tracking (APT) table stored in a memory. The APT table may store information on a necessary power supply voltage of the power amplifier PA based on expected output power (or a transmission power) of the antenna ANT and information on an average power signal corresponding to the necessary power supply voltage of the power amplifier PA. Accordingly, when the expected output power of the antenna ANT is determined, the modem 310 may generate the average power signal D_REF using the APT table and may provide the generated average power signal D_REF to the supply modulator 340 as a reference voltage signal.

The digital processing circuit 311 may perform various processing operations on a baseband signal in a digital domain.

For example, the digital processing circuit 311 may perform the above-described average power signal generation, envelope extraction, digital envelope signal generation, crest factor reduction (CFR), shaping function (SF), digital pre-distortion (DPD), delay compensation operation, or the like.

CFR may reduce a peak-to-average power ratio (PAPR) of the communication signal (for example, the baseband signal BB_T). SF may modify the digital envelope signal D_ENV to improve efficiency and linearity of the power amplifier PA. DPD may compensate for distortion of the power amplifier PA in the digital domain to linearize the distortion. In addition, the delay compensation operation may correct a delay of the digital envelope signal D_ENV or the baseband signal BB_T.

The digital processing circuit 311 may output the digital envelope signal D_ENV and the baseband signal BB_T. The digital envelope signal D_ENV may be converted into an analog envelope signal A_ENV through the first DAC 312 and provided to the power modulator 340, and the baseband signal BB_T may be converted into a transmit signal TX through the second DAC 313 and provided to the transmission circuit TXC.

The digital processing circuit 311 may further include internal components for processing the above-described operations (for example, baseband signal processing, envelope extraction, digital envelope signal generation, or the like).

For example, the second DAC 313 and ADC 314 may include at least one second DAC and at least one ADC, respectively. The modem 310 may perform digital-to-analog conversion on the baseband signal BB_T using the second DAC 313 to generate the transmit signal TX. In addition, the modem 310 may receive a receive signal RX, an analog signal, from the RFIC 320. Also, the modem 310 may perform analog-to-digital conversion on the receive signal RX using the ADC 314 provided therein to extract a baseband signal BB_R, a digital signal. For example, the receive signal RX may be a differential signal including a positive signal and a negative signal.

The RFIC 320 may perform frequency up-conversion on the transmit signal TX to generate an RF input signal RF_IN, or perform frequency down-conversion on the RF receive signal RF_R to generate a receive signal RX. For example, the RFIC 320 may include a transmit circuit TXC for frequency up-conversion, a receive circuit RXC for frequency down-conversion, a local oscillator LO, a power amplifier PA, and a coupler 323.

The transmit circuit TXC may include a first analog baseband filter ABF1 and a first mixer MX1 and a driver amplifier 321. For example, the first analog baseband filter ABF1 may include a low-pass filter.

The first analog baseband filter ABF1 may filter the transmit signal TX received from the modem 310 and provide the filtered transmit signal TX to the first mixer MX1. The first mixer MX1 may perform frequency up-conversion for converting a frequency of the transmit signal TX from a baseband to a high-frequency band through a frequency signal provided by the local oscillator LO. The transmit signal TX may be provided to the driver amplifier 321 as the RF input signal RF_IN through the frequency up-conversion, and the driver amplifier 321 may amplify power of the RF input signal RF_IN and supply the amplified power to the power amplifier PA.

The power amplifier PA may be supplied with a DC voltage or a power supply voltage (for example, a dynamically variable output voltage), and may amplify power of the RF input signal RF_IN based on the supplied power supply voltage to generate an RF output signal RF_OUT. The power amplifier PA may provide the generated RF output signal RF_OUT to the duplexer 400 through the coupler 323.

The reception circuit RXC may include a second analog baseband filter ABF2, a second mixer MX2, and a low-noise amplifier (LNA) 322. For example, the second analog baseband filter ABF2 may include a low-pass filter.

The LNA 322 may amplify the RF receive signal RF_R provided from the duplexer 400 and provide the amplified RF receive signal RF_R to the second mixer MX2. The second mixer MX2 may perform frequency down-conversion to convert a frequency of the RF receive signal RF_R from a high-frequency band to a baseband through a frequency signal provided by the local oscillator LO. For example, the second mixer MX2 may convert the RF receive signal RF_R into a baseband signal using the LO signal.

Such frequency down-conversion may allow the RF receive signal RF_R corresponding to the baseband signal to be provided as a receive signal RX to the second analog baseband filter ABF2, and allow the second analog baseband filter ABF2 to filter and provide the receive signal RX corresponding to the baseband signal to the modem 310.

The coupler 323 may couple amplified signals output from the power amplifier PA and provide the coupled signal to the duplexer 330. The coupler 323 may be configured as described above, for example with reference to FIGS. 1 to 14 and FIG. 18, or may include the first unit circuit, the second unit circuit, and the isolation resistor.

The power amplifier PA and the coupler 323 may be connected through a differential line pair, and the coupler 323 and the duplexer 330 may be connected through a single-ended line. The coupler 323 may provide impedance matching and signal conversion between the differential line pair and the single-ended line.

For reference, the wireless communication device 300 may transmit a transmit signal through a plurality of frequency bands using carrier aggregation (CA). To this end, the wireless communication device 300 may include a plurality of power amplifiers Pas power-amplifying the plurality of RF input signals RF_IN, respectively corresponding to the plurality of carriers. However, for ease of description, an example is provided in which there is only one power amplifier PA.

The duplexer 330 may be connected to the antenna ANT to separate a transmit frequency and a receive frequency. For example, the duplexer 330 may separate the RF output signal RF_OUT, provided from the power amplifier PA, for each frequency band and provide the separated RF output signal RF_OUT to the corresponding antenna ANT. Also, the duplexer 330 may provide an external signal, provided from the antenna ANT, to the LNA 322 included in the RF circuit 322 of the receive circuit RXC of the RFIC 320. For example, the duplexer 330 may include a front end module with integrated duplexer (FEMiD).

For reference, the wireless communication device 300 may include a switch structure, capable of separating the transmit frequency and the receive frequency, instead of the duplexer 400. Also, the wireless communication device 300 may include a structure including the duplexer 400 and a switch to separate the transmit frequency and the receive frequency. However, for ease of description, an example is provided in which the duplexer 400, capable of separating the transmit frequency and the receive frequency, is included in the wireless communication device 300.

The power modulator 340 may generate a modulated output voltage having a level varying dynamically based on an analog envelope signal A_ENV and an average power signal D_REF, and may provide the output voltage as a supply voltage of the power amplifier PA.

For example, the power modulator 340 may receive an average power signal D_REF and an analog envelope signal A_ENV from the modem 310. And, the power modulator 340 may operate in either ET mode or APT mode based on the received average power signal D_REF and analog envelope signal A_ENV to generate a dynamically variable output voltage. Also, the power modulator 340 may provide the generated output voltage as a power supply voltage to the power amplifier PA.

For reference, when a power supply voltage having a fixed level is applied to the power amplifier PA, the power efficiency of the power amplifier PA may be reduced. Therefore, the power modulator 340 may modulate an input voltage (for example, power provided from a battery) based on at least one of the analog envelope signal A_ENV and the average power signal D_REF and provide the modulated voltage as a power supply voltage to the power amplifier PA to efficiently manage the power of the power amplifier PA.

The antenna ANT may transmit the RF output signal RF_OUT that has been frequency-separated by the duplexer 330 to the outside, or may provide an RF receive signal RF_R received from the outside to the duplexer 330. For example, the antenna ANT may include an array antenna, but example embodiments are not limited thereto.

For reference, the modem 310, the RFIC 320, the power amplifier PA, the duplexer 330, and the power modulator 340 may be individually implemented as an IC, a chip, or a module. Also, the modem 310, the RFIC 320, the power amplifier PA, the duplexer 330, and the power modulator 340 may be mounted together on a printed circuit board (PCB), but example embodiments are not limited thereto. In some example embodiments, at least a portion of the modem 310, the RFIC 320, the duplexer 330, and the power modulator 340 may be implemented as a single communication chip.

Furthermore, the wireless communication device 300 illustrated in FIG. 20 may be included in a wireless communication system using a cellular network such as 5G or LTE, or may be included in a wireless local area network (WLAN) system or other arbitrary wireless communication system. For reference, the configuration of the wireless communication device 300 illustrated in FIG. 20 is only an example and example, and example embodiments are not limited thereto and the wireless communication device 300 may have various configurations depending on the communication protocol or communication scheme.

As set forth above, according to example embodiments, a coupler for amplified signal coupling and a chip including the same may be provided.

While aspects of example embodiments have been shown and described above, it will be apparent to those skilled in the art that modifications and variations may be made without departing from the scope of the present inventive concept as defined by the appended claims.

What is claimed is:

1. A coupler comprising:
a first unit circuit connected between a first differential line pair and a single-ended line;
a second unit circuit connected between a second differential line pair and the single-ended line;
a plurality of transmission lines comprising a first group of transmission lines connected between the first differential line pair and a crossed differential line pair, and a second group of transmission lines connected between the second differential line pair and the crossed differential line pair; and
an isolation resistor connected to the crossed differential line pair,
wherein the first unit circuit comprises:
a first transformer having a first side connected to the first differential line pair and a second side connected to the single-ended line; and
a second-side capacitor connected in parallel to the second side of the first transformer, and
wherein the second unit circuit comprises:
a second transformer having a first side connected to the second differential line pair and a second side connected to the single-ended line; and
a second-side capacitor connected in parallel to the second side of the second transformer.

2. The coupler of claim 1, wherein the first unit circuit comprises a first-side capacitor connected in parallel to the first side of the first transformer, and the second unit circuit further comprises a first-side capacitor connected in parallel to a first side of the second transformer.

3. The coupler of claim 1, wherein the isolation resistor has an impedance equal in magnitude to a differential characteristic impedance defined in the first differential line pair.

4. The coupler of claim 1, wherein each of the first transformer and the second transformer has a turn ratio of 2:1.

5. The coupler of claim 1, wherein the crossed differential line pair comprises a crossed anode line and a crossed cathode line intersecting the crossed anode line in at least some regions.

6. The coupler of claim 5, wherein the first group of transmission lines comprises:
a first transmission line connected to a first anode line of the first differential line pair and the crossed cathode line; and
a second transmission line connected to a first cathode line of the first differential line pair and the crossed anode line.

7. The coupler of claim 6, wherein the second group of transmission lines further comprises:
a third transmission line connected to a second anode line of the second differential line pair and the crossed anode line; and
a fourth transmission line connected to a second cathode line of the second differential line pair and the crossed cathode line.

8. The coupler of claim 1, wherein the plurality of transmission lines have a common characteristic impedance and cause a common phase difference.

9. The coupler of claim 8, wherein the common characteristic impedance is 1/\sqrt{2} times a differential characteristic impedance defined in the first differential line pair.

10. The coupler of claim 8, wherein the common phase difference is 90 degrees.

11. A coupler comprising:
a first unit circuit connected between a first differential line pair and a single-ended line;
a second unit circuit connected between a second differential line pair and the single-ended line;
a first line circuit connected between the first differential line pair and a crossed differential line pair;
a second line circuit connected between the second differential line pair and the crossed differential line pair; and
an isolation resistor connected to the crossed differential line pair,
wherein the first and unit circuit comprises:
a first transformer having a first side connected to the first differential line pair, and a second side connected to the single-ended line; and
a second-side capacitor connected in parallel to the second side of the first transformer, and
wherein the second unit circuit comprises:
a second transformer having a first side connected to the second differential line pair, and a second side connected to the single-ended line; and
a second-side capacitor connected in parallel to the second side of the second transformer.

12. The coupler of claim 11, wherein the first line circuit comprises:
a first inductor connected to a first anode line of the first differential line pair and a crossed cathode line of the crossed differential line pair;
a second inductor connected to a first cathode line of the first differential line pair and a crossed anode line of the crossed differential line pair; and
a first capacitor connected in parallel to the isolation resistor.

13. The coupler of claim 12, wherein the second line circuit comprises:
a third inductor connected to a second anode line of the second differential line pair and the crossed anode line;
a fourth inductor connected to a second cathode line of the second differential line pair and the crossed cathode line; and
a second capacitor connected in parallel to the isolation resistor.

14. The coupler of claim 13, wherein the first line circuit further comprises a third capacitor connected to the first differential line pair, and
wherein the second line circuit further comprises a fourth capacitor connected to the second differential line pair.

15. The coupler of claim 11, wherein the first unit circuit further comprises a first-side capacitor connected in parallel to the first side of the first transformer, and the second unit circuit further comprises a first-side capacitor connected in parallel to the first side of the second transformer.

16. The coupler of claim 11, wherein the isolation resistor has an impedance equal in magnitude to a differential characteristic impedance defined in the first differential line pair.

17. The coupler of claim 11, wherein each of the first transformer and the second transformer has a turn ratio of 2:1.

18. A chip comprising:
a first amplifier configured to output a first amplified signal through a first differential line pair;
a second amplifier configured to output a second amplified signal through a second differential line pair; and
a coupler connected to the first differential line pair and the second differential line pair, and configured to couple the first amplified signal and the second amplified signal and output a coupled signal through a single-ended line,
wherein the coupler comprises:
a first transformer having a first side connected to the first differential line pair and a second side connected to the single-ended line;
a first capacitor connected in parallel to the second side of the first transformer;
a second transformer having a first side connected to the second differential line pair and a second side connected to the single-ended line;
a second capacitor connected in parallel to the second side of the second transformer;
a first line circuit connected between the first differential line pair and a crossed differential line pair;
a second line circuit connected between the second differential line pair and the crossed differential line pair; and
an isolation resistor connected to the crossed differential line pair.

19. The chip of claim 18, wherein the first line circuit comprises:
a first inductor connected to a first anode line of the first differential line pair and a crossed cathode line of the crossed differential line pair;
a second inductor connected to a first cathode line of the first differential line pair and a crossed anode line of the crossed differential line pair; and
a third capacitor connected in parallel to the isolation resistor.

20. The chip of claim 19, wherein the second line circuit comprises:
a third inductor connected to a second anode line of the second differential line pair and the crossed anode line;
a fourth inductor connected to a second cathode line of the second differential line pair and the crossed cathode line; and
a fourth capacitor connected in parallel to the isolation resistor.
